(19) United States
(12) Patent Application Publication
(10) Pub. No.: US 2009/0040740 A1
(43) Pub. Date: Feb. 12, 2009

(54) Wiring circuit board

(75) Inventors: Karl Muller, Donaueschingen/Heidenhofen (DE); Joachim Borst, Donaueschingen (DE)

Correspondence Address: THE NATH LAW GROUP, 112 South West Street, Alexandria, VA, 22314, US

(73) Assignee: MC TECHNOLOGY GmbH, Blumberg (DE)

(21) Appl. No.: 12/222,289

(22) Filed: Aug. 6, 2008

(30) Foreign Application Priority Data
Aug. 9, 2007 (DE) 20 2007 011 113.4

(51) Int. Cl. H05K 1/14

(52) U.S. Cl. 361/785

(57) ABSTRACT

Wiring circuit board for connecting an electronic control system or an electronic control module to a connection circuit board, on which service lines for the electronic control system or the electronic control module can be hooked up in terminals, wherein the wiring circuit board has a plug and socket connector, which can be plugged directly or via a connection cable into a mating connector of the connection circuit board, which is in electrically conducting connection with the terminals of the connection circuit board, and at least one socket, into which the electronic control system or the electronic control module can be plugged, and the plug and socket connector is joined in electrical conduction via the wiring circuit board to the at least one socket.

The invention concerns a wiring circuit board for connecting an electronic control system or an electronic control module to with a service wire board, on which service wires for the electronic control system or the electronic control module can be connected in connection terminals.

When remodeling buildings, generally the control systems of the building automation, such as controls for doors, window shades, heating systems or air conditioning, need to be replaced by more modern control systems. In traditional control systems, there are two subassemblies present, namely, a connection circuit board, which has connection terminals for hooking up the service lines, and an electronic circuit board, which contains the actual control system. The two subassemblies are generally joined together by plug and socket connectors or plug-in lines.

The drawback here is that all electronic components are hard wired on the electronic circuit board and therefore when s single component fails the entire electronic circuit board needs to be replaced. But such electronic circuit boards for older equipment are no longer being manufactured today. Today, the electronic circuit board is being replaced by an electronic control system or individual control modules. Now, in order to replace the traditional control systems during a building remodel, it is therefore necessary to remove all service lines from the connection terminals of the connection circuit boards and reconnect them to the new control systems or control modules. This takes a lot of time, since a single connection circuit board generally has many service lines hooked up to it, such as 100 or 200 service lines, which results in considerable problems during the ongoing operation of a building, because the electronic control units have to be shut down during this time. Furthermore, there is a danger that the service lines will get mixed up and therefore the control systems will not work right when placed back in operation.

Thus, the problem of the invention is to create a possibility of replacement of control systems in a brief time.

The problem is solved by a wiring circuit board with the features of claim 1.

Advantageous embodiments and modifications of the invention are indicated in the subclaims.

The invention is based on the understanding that the disconnecting of the service lines from the connection circuit board and the reconnecting of these service lines is especially time-consuming and should thus be avoided. Since no complete electronic circuit boards are being manufactured at present that would enable such a simple and not very time-consuming replacement, the invention consists in providing a wiring circuit board which can be inserted by a plug and socket connector into a mating connector of the connection circuit board and which has at least one socket into which the electronic control system or the electronic control modules can be plugged. Through the wiring circuit board, the plug and socket connector is joined in electrical conduction to the at least one socket. By providing the wiring circuit board, on which sockets for particular control systems or particular control modules can be joined in electrical conduction to the plug and socket connector and, via this, to the respective connection terminals on the connection circuit board, there is no need to undo the connections between the service lines and the connection terminals on the connection circuit board in order to connect the respective service lines directly into the electronic control system or the electronic control module. A replacement of the electronic circuit board by the wiring circuit board, on which the respective electronic control systems or electronic control modules can be inserted, can be done in much shorter time, and wiring mistakes can be ruled out. Also, if afterwards individual control modules or the electronic control system should malfunction, the control system or the control modules can then be replaced by simply undoing the plug and socket connection to the sockets and plugging in the new control system or the new control module, for which only a brief time is required, unlike the undoing of all corresponding service lines and connecting of the respective service lines directly to the new electronic control system or the new electronic control module.

According to the invention, the wiring circuit board has conducting tracks in at least two, preferably several layers, so that the wiring circuit board is constructed as compact as possible.

In one advantageous modification, sockets are arranged on both sides of the wiring circuit board, in order to arrange the electronic control systems or the electronic control modules as compactly as possible on the wiring circuit board. Several electronic control systems or control modules can be joined together preferably via a bus system arranged on the wiring circuit board or also externally via plug-in bridges, in order to imitate the corresponding functionality of a compact control system.

If the electronic control system or the electronic control module are not pluggable directly in the socket, for example, because they have terminals for connecting the service lines, an adapter board is preferably provided, which has a circuit board with at least two pins, which can be introduced into the connections for the service lines of the electronic control system or the electronic control module, and a plug and socket connector, which can be plugged into the socket, so as to make the electronic control system or the electronic control module pluggable in this way, so that it can easily be plugged into the socket of the wiring circuit board.

The invention shall be explained in detail by means of the following figures. These show:

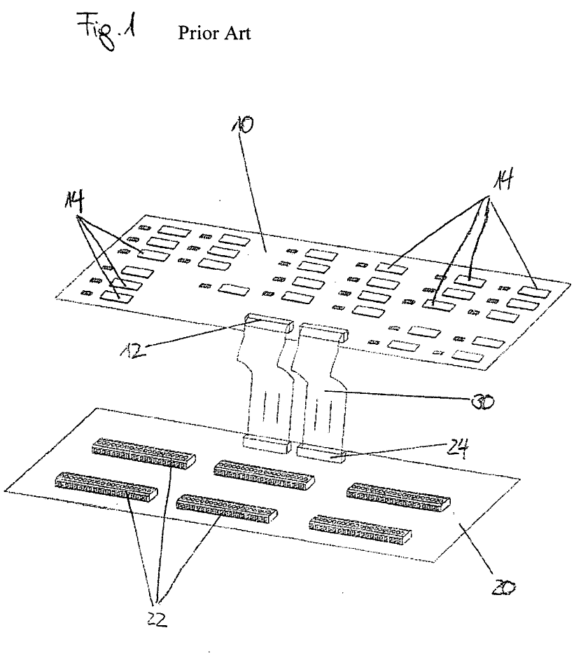

FIG. 1 a control system of the prior art, and

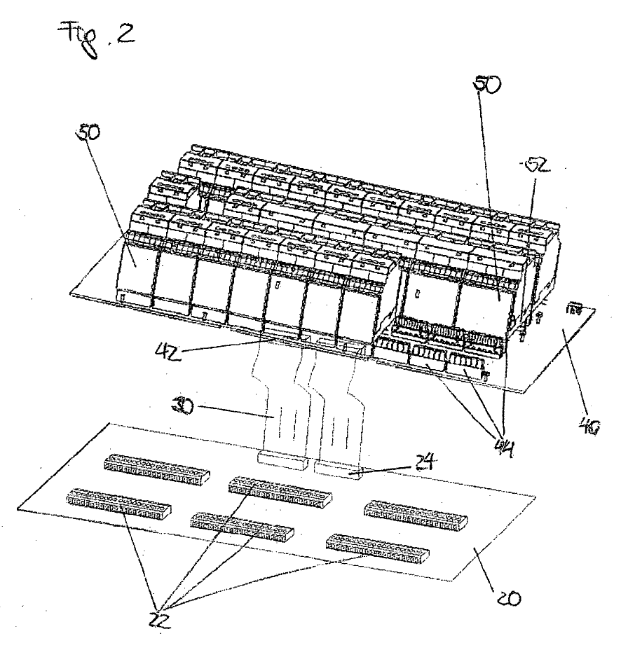

FIG. 2 a control system with a wiring circuit board according to the invention.

FIG. 1 shows a control system of a building automation in the prior art. This control system has two subassemblies, namely, an electronic circuit board 10 and a connection circuit board 20. The electronic circuit board 10 shows several electronic components 14, which have the actual control system, while the electronic circuit board 10 can be connected via a plug and socket connector 12 either directly or via a connection cable 30 to a mating connector 24 arranged on the connection circuit board 20. Several terminals 22 are arranged on the connection circuit board 20, in which service lines (not shown) can be hooked up, and from each terminal 22 respective conducting tracks on the connection circuit board 20 lead to the mating connector 24, which communicates in electrically conducting manner with the plug and socket connector 12 via the connection cable 30, and corresponding conducting tracks starting at the plug and socket connector 12 are arranged on the electronic circuit board 10 in such a way that the service lines introduced into the terminals 22 are in electrically conducting communication with the respective electronic components 14.

Since such electronic circuit boards 10 are no longer being produced today, but rather only individual control systems or individual control modules 50 as shown in FIG. 2 are being produced, when an electronic component 14 of the electronic circuit board 10 fails today it is necessary to remove all of the service lines connected to the terminals 22 and hook them up directly into the control modules 50, possibly via terminals.

But since such an undoing of all service lines from the terminals 22 is very time consuming and can result in long down time for the building components operated by the control system, a wiring circuit board 40 is provided according to the invention, as shown in FIG. 2, which has a plug and socket connector 42 compatible with the mating connector 24 or the connection cable 30. Several sockets 44 are provided on the wiring circuit board 40, into which the control modules 50 can be plugged, especially via a plug and socket connector 52. The control modules 50 can either have a plug and socket connector 52 directly or they can be pluggable via an adapter board. The adapter board has, e.g., a circuit board, on which the plug and socket connector 52 and several pins are arranged, while the pins can be plugged into the terminals of the control modules 50 that are provided for the service lines. Through the circuit board, the pins are connected in electrical conduction to the plug and socket connector 52. The control modules 50 are plugged into the sockets 44 via the plug and socket connector 53, so that an electrically conducting contact is produced.

Between the sockets 44 and the plug and socket connector 42 are provided corresponding conducting tracks on the wiring circuit board 40, which produce the electrically conducting connection between the socket 44 via the plug and socket connector 42 and the mating connector 24 to the respective terminal 22 on the connection circuit board 20.

If, then, the electronic circuit board 10 of the prior art needs to be replaced during a building remodel, a wiring circuit board 40 with the corresponding control modules 50 can be provided, so that only the connection between the traditional plug and socket connector 12 of the electronic circuit board 10 and the connection cable 30 need be undone in the shortest time and the connection cable can be connected to the plug and socket connector 42 of the wiring circuit board 40. A time consuming undoing of all service lines connected to the terminals 22 and a reconnecting of these service lines in the control modules 50 is entirely unnecessary. Thus, the replacement of the traditional control systems is reduced to the minimum, and wiring mistakes by mixing up the service lines in the terminals are ruled out. Also in future if one of the control modules 50 should malfunction or need to be replaced by a more modern control module 50, this control module 50 can easily be undone from the socket 44 and be replaced by a new control module 50, which is merely inserted into the socket 44. The wiring already present remains intact, so that the replacement can be done in the shortest time. Time-consuming rewiring is then avoided.

The connecting of the individual control modules 50 can be done either via the wiring circuit board 40 by providing an appropriate bus system on the wiring circuit board 40, or alternatively the control modules 50 can also be joined to each other via external plug-in bridges, which are inserted into corresponding plug and socket connectors of the control modules 50, in order to form a corresponding control system.

In the wiring circuit board 40 shown in FIG. 2, all the sockets 44 are arranged on one side of the wiring circuit board 40. In order to achieve the most compact design, however, it is basically possible to provide further sockets 44 on the back side of the wiring circuit board 40.

### LIST OF REFERENCE NUMBERS

10 Electronic circuit board

12 Plug and socket connector

14 Electronic component

20 Connection circuit board

22 Terminal

24 Mating connector

30 Connection cable

40 Wiring circuit board

42 Plug and socket connector

44 Socket

50 Control module

52 Plug and socket connector

1. Wiring circuit board (40) for connecting an electronic control system or an electronic control module (50) to a connection circuit board (20), on which service lines for the electronic control system or the electronic control module (50) can be hooked up in terminals (22), wherein the wiring circuit board (40) has a plug and socket connector (42), which can be plugged directly or via a connection cable (30) into a mating connector (24) of the connection circuit board (20), which is in electrically conducting connection with the terminals (22) of the connection circuit board (20), and at least one socket (44), into which the electronic control system or the electronic control module (50) can be plugged, and the plug and socket connector (42) is joined in electrical conduction via the wiring circuit board (40) to the at least one socket (44).

2. Wiring circuit board per claim 1 characterized in that the wiring circuit board (40) has conducting tracks in at least two, preferably several layers.

3. Wiring circuit board per claim 1,
characterized in that
sockets (44) are arranged on both sides of the wiring circuit board (40).

4. Wiring circuit board per claim 1,
characterized in that
several electronic control systems or control modules (50) are joined together via a bus system on the wiring circuit board (40).

5. Wiring circuit board per claim 1,
characterized in that
several electronic control systems or control modules (50) are joined together via plug-in bridges.

6. Wiring circuit board per claim 1,
characterized in that
the electronic control system or the at least one control module (50) has an adapter board, which has a circuit board with at least two pins, which can be introduced into connections for the service lines of the electronic control system or the electronic control module (50), and a plug and socket connector (52), which can be plugged into the socket (44).
